(19) United States
(12) Patent Application Publication
(10) Pub. No.: US 2013/0078801 A1
(43) Pub. Date: Mar. 28, 2013

(54) MANUFACTURE METHODS OF DOUBLE LAYER GATE ELECTRODE AND RELEVANT THIN FILM TRANSISTOR

(71) Applicants: Chengcai Dong, Shenzhen (CN); Jehao Hsu, Shenzhen (CN)

(72) Inventors: Chengcai Dong, Shenzhen (CN); Jehao Hsu, Shenzhen (CN)

(73) Assignee: SHENZHEN CHINA STAR OPTOELECTRONICS TECHNOLOGY CO.,LTD., Shenzhen (CN)

(21) Appl. No.: 13/378,046

(22) PCT Filed: Oct. 7, 2011
(86) PCT No.: PCT/CN2011/080515

§ 371 Date: Dec. 14, 2011

(30) Foreign Application Priority Data
Sep. 22, 2011 (CN) 201110283366.0

(51) Int. Cl. H01L 21/283

(52) U.S. Cl. 438/656; 257/E21.159

(57) ABSTRACT

Disclosed is a manufacture method of a double layer gate electrode by patterning the photoresist layer with a half tone mask to make thicknesses of two sides of the photoresist layer are smaller than a thickness of middle of the photoresist layer and twice wet etchings thereafter to realize the manufacture of the double layer gate electrode. The present invention also relates to a manufacture method of a thin film transistor. The manufacture methods of a double layer gate electrode and a relevant thin film transistor according to the present invention employs half tone mask and twice wet etchings thereafter for manufacturing the gate electrode to solve technical problems of high manufacture cost and great manufacture difficulty of double layer gate electrodes according to prior arts.

### BACKGROUND OF THE INVENTION

1. Field of the Invention

The present invention generally relates to a semiconductor manufacture field, and more particularly to a manufacture methods of a double layer gate electrode and a relevant thin film transistor by employing a half tone mask for photolithography and twice wet etchings thereafter.

2. Description of Prior Art

The gate electrode of the Thin Film Transistor generally comprises two metal films (such as an aluminum metal film and a molybdenum metal film). Two metal films are thicker and two metal films with a single layer structure shown in FIG. 1 are formed, the deposition of the following layers can be unfavorably affected. A major way to solve such problem according to prior art is to etch the aluminum metal layer 25 to be narrower than the molybdenum metal layer 23 to form a double layer structure shown in FIG. 2. The gate electrode is changed from a single layer structure to a double layer structure in the thickness direction.

A manufacturing method of a double layer gate electrode is proposed according to prior art:

One wet etching and one dry etching utilized for forming the gate electrode are specifically described below:
1. As shown in FIG. 3, a molybdenum metal layer 23 and an aluminum metal layer 25 are deposited and a photoresist layer 27 is coated. After a first photolithography, the photoresist layer with a width W1 is formed;
2. A wet etching is implemented to form a structure shown in FIG. 4;
3. A dry etching is implemented to strip the photoresist layer to form the structure shown in FIG. 2. The double layer gate electrode 29 is obtained. The width of the molybdenum metal layer 23 is W1 and the width of the aluminum metal layer 25 is W2;

The drawbacks of such manufacture method is that the substrate needs to be transferred in different chambers because the different process conditions of the wet etching and dry etching and the manufacture cost and the manufacture difficulty are raised.

Consequently, there is a need to provide manufacture methods of a double layer gate electrode and a relevant thin film transistor to solve the existing problems of prior arts.

### SUMMARY OF THE INVENTION

An objective of the present invention is to provide a manufacture method of a double layer gate electrode employing half tone mask and twice wet etchings thereafter and a manufacture method of a relevant thin film transistor to solve technical problems of high manufacture cost and great manufacture difficulty of double layer gate electrodes according to prior arts.

For solving the aforesaid problems, the present invention relates to a manufacture method of a double layer gate electrode comprising steps of: S10, depositing a first metal layer, a second metal layer and a photoresist layer; S20, patterning the photoresist layer with a half tone mask to make thicknesses of two sides of the photoresist layer are smaller than a thickness of middle of the photoresist layer, and a width of the thicker part of the photoresist layer is a first width, and a width of the photoresist layer is a second width; S30, conducting wet etching to shape the first metal layer and the second metal layer as a single layer structure; S40, removing the thinner part of the photoresist layer at the two sides by photoresist ashing; S50, conducting wet etching to diminish a width of the second metal layer to the first width; S60, conducting photoresist stripping to the photoresist layer; the width of the second metal layer is the first width and a width of the first metal layer is the second width after the step S60; the middle of the half tone mask is an opaque layer and two sides of the half tone mask are semiopaque layers, and a width of the half tone mask is the second width and a width of the opaque layer is the first width; a weight distribution of an etching liquid of the wet etching is: H3PO4 50-60%: HNO3 10-20%: CH3COOH 2-10%: H2O 20-30%; the photoresist ashing is to employ ultraviolet light to cut chemical bonds of the photoresist in the photoresist layer and to utilize ozonolysis oxygen radical to react with and remove the photoresist layer; a temperature of the photoresist ashing is 80 degree Celsius to 120 degree Celsius; the first metal layer is an aluminum metal layer; the second metal layer is a molybdenum metal layer.

The present invention also relates to a manufacture method of a double layer gate electrode comprising steps of: S10, depositing a first metal layer, a second metal layer and a photoresist layer; S20, patterning the photoresist layer with a half tone mask to make thicknesses of two sides of the photoresist layer are smaller than a thickness of middle of the photoresist layer, and a width of the thicker part of the photoresist layer is a first width, and a width of the photoresist layer is a second width; S30, conducting wet etching to shape the first metal layer and the second metal layer as a single layer structure; S40, removing the thinner part of the photoresist layer at the two sides by photoresist ashing; S50, conducting wet etching to diminish a width of the second metal layer to the first width; S60, conducting photoresist stripping to the photoresist layer.

In the manufacture method of the double layer gate electrode according to the present invention, the width of the second metal layer is the first width and a width of the first metal layer is the second width after the step S60.

In the manufacture method of the double layer gate electrode according to the present invention, the middle of the half tone mask is an opaque layer and two sides of the half tone mask are semiopaque layers, and a width of the half tone mask is the second width and a width of the opaque layer is the first width.

In the manufacture method of the double layer gate electrode according to the present invention, a weight distribution of an etching liquid of the wet etching is: H3PO4 50-60%: HNO3 10-20%: CH3COOH 2-10%: H2O 20-30%.

In the manufacture method of the double layer gate electrode according to the present invention, the photoresist ashing is to employ ultraviolet light to cut chemical bonds of the photoresist in the photoresist layer and to utilize ozonolysis oxygen radical to react with and remove the photoresist layer.

In the manufacture method of the double layer gate electrode according to the present invention, a temperature of the photoresist ashing is 80 degree Celsius to 120 degree Celsius.

In the manufacture method of the double layer gate electrode according to the present invention, the first metal layer is an aluminum metal layer.

In the manufacture method of the double layer gate electrode according to the present invention, the second metal layer is a molybdenum metal layer.

The present invention also relates to a manufacture method of a thin film transistor, wherein the manufacture method comprises a manufacture of a double layer gate electrode, comprising steps of: S10, depositing a first metal layer, a second metal layer and a photoresist layer; S20, patterning the photoresist layer with a half tone mask to make thicknesses of two sides of the photoresist layer are smaller than a thickness of middle of the photoresist layer, and a width of the thicker part of the photoresist layer is a first width, and a width of the photoresist layer is a second width; S30, conducting wet etching to shape the first metal layer and the second metal layer as a single layer structure; S40, removing the thinner part of the photoresist layer at the two sides by photoresist ashing; S50, conducting wet etching to diminish a width of the second metal layer to the first width; S60, conducting photoresist stripping to the photoresist layer.

In the manufacture method of the thin film transistor according to the present invention, the width of the second metal layer is the first width and a width of the first metal layer is the second width after the step S60.

In the manufacture method of the thin film transistor according to the present invention, the middle of the half tone mask is an opaque layer and two sides of the half tone mask are semiopaque layers, and a width of the half tone mask is the second width and a width of the opaque layer is the first width.

In the manufacture method of the thin film transistor according to the present invention, a weight distribution of an etching liquid of the wet etching is: H3PO4 50-60%: HNO3 10-20%; CH3COOH 2-10%: H2O 20-30%.

In the manufacture method of the thin film transistor according to the present invention, the photoresist ashing is to employ ultraviolet light to cut chemical bonds of the photoresist in the photoresist layer and to utilize ozonolysis oxygen radical to react with and remove the photoresist layer; a temperature of the photoresist ashing is 80 degree Celsius to 120 degree Celsius.

In the manufacture method of the thin film transistor according to the present invention, the first metal layer is an aluminum metal layer and the second metal layer is a molybdenum metal layer.

Comparing with the manufacture methods of a double layer gate electrode and a relevant thin film transistor having technical problems of high manufacture cost and great manufacture difficulty according to prior art, the manufacture methods of a double layer gate electrode and a relevant thin film transistor according to the present invention employs half tone mask and twice wet etchings thereafter. The substrate does not need to be transferred in different chambers. Therefore, both the manufacture cost and the manufacture difficulty are low.

For a better understanding of the aforementioned content of the present invention, preferable embodiments are illustrated in accordance with the attached figures for further explanation:

### BRIEF DESCRIPTION OF THE DRAWINGS

FIG. 1 depicts a structure diagram of a single layer gate electrode having two metal layers according to prior arts;

FIG. 2 depicts the first structure diagram of manufacturing a single layer gate electrode having two metal layers according to prior arts;

FIG. 3 depicts the second structure diagram of manufacturing a single layer gate electrode having two metal layers according to prior arts;

FIG. 4 depicts the third structure diagram of manufacturing a single layer gate electrode having two metal layers according to prior arts;

FIG. 5 depicts the first structure diagram of a preferable embodiment according to a manufacture method of a double layer gate electrode of the present invention;

FIG. 6 depicts the second structure diagram of a preferable embodiment according to a manufacture method of a double layer gate electrode of the present invention;

FIG. 7 depicts the third structure diagram of a preferable embodiment according to a manufacture method of a double layer gate electrode of the present invention;

FIG. 8 depicts the fourth structure diagram of a preferable embodiment according to a manufacture method of a double layer gate electrode of the present invention;

FIG. 9 depicts the fifth structure diagram of a preferable embodiment according to a manufacture method of a double layer gate electrode of the present invention;

FIG. 10 depicts the sixth structure diagram of a preferable embodiment according to a manufacture method of a double layer gate electrode of the present invention;

FIG. 11 shows a flowchart of a preferable embodiment according to a manufacture method of a double layer gate electrode of the present invention.

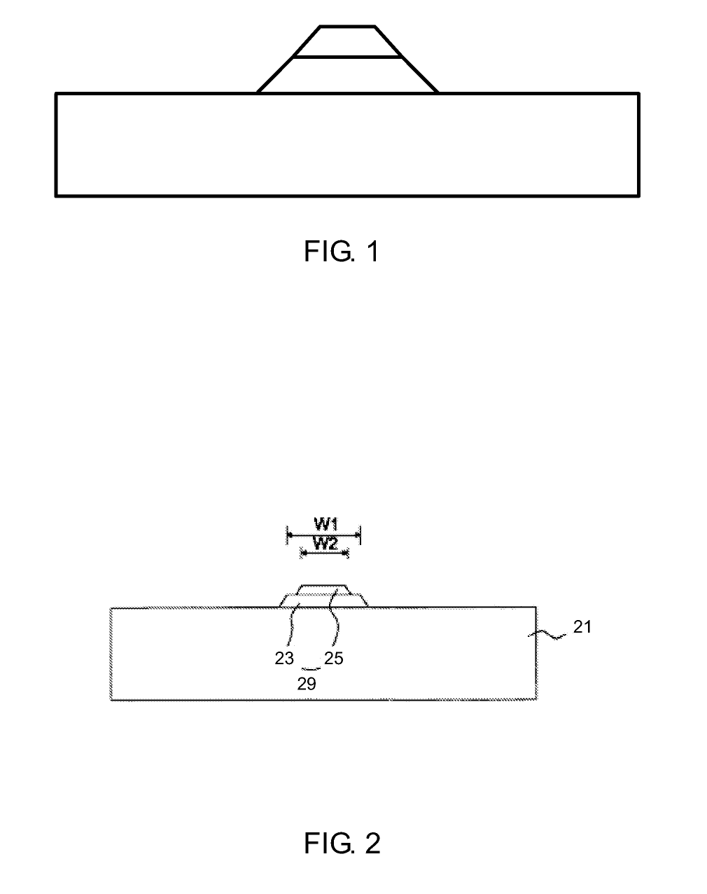

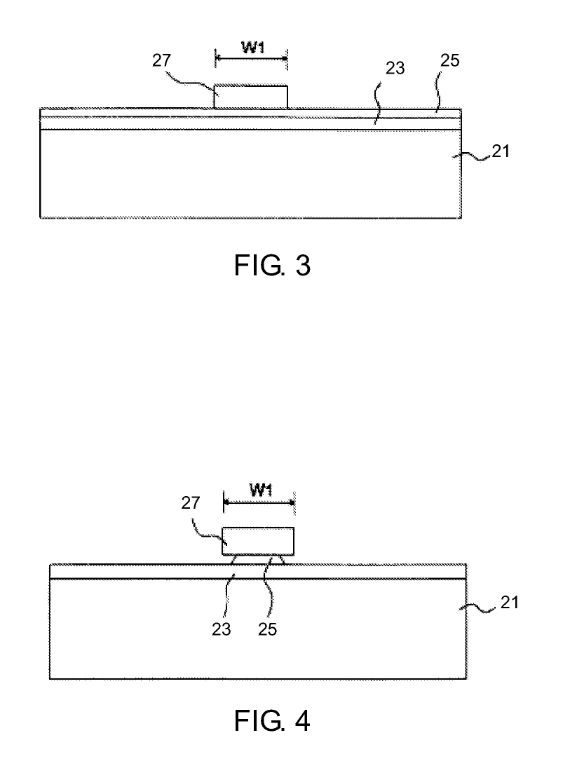

### DETAILED DESCRIPTION OF THE INVENTION

The following descriptions for the respective embodiments are specific embodiments capable of being implemented for illustrations of the present invention with referring to appended figures. For example, the terms of up, down, front, rear, left, right, interior, exterior, side, etcetera are merely directions of referring to appended figures. Therefore, the wordings of directions are employed for explaining and understanding the present invention but not limitations thereto.

In figures, the elements with similar structures are indicated by the same number.

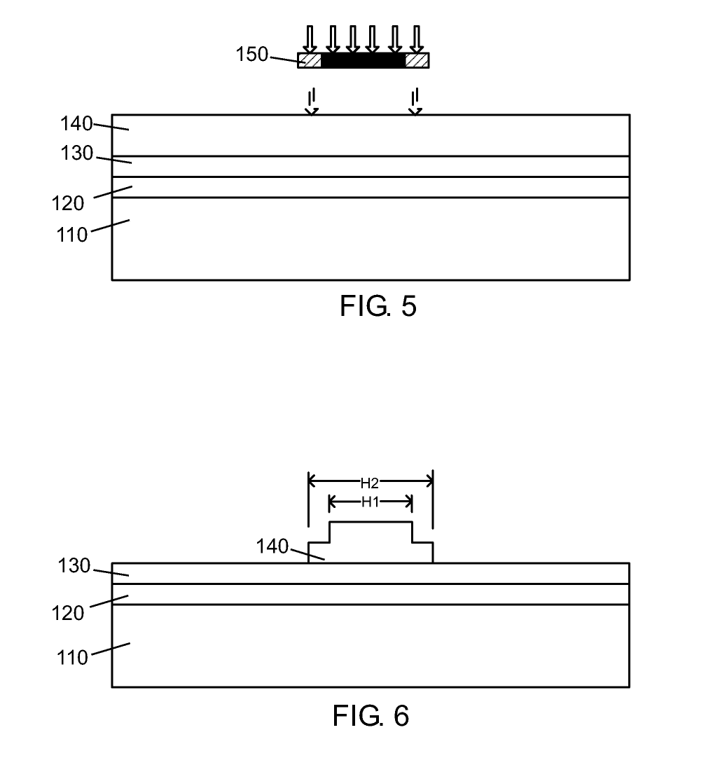

The manufacture method of the double layer gate electrode according to the present invention employs half tone mask for patterning the corresponding photoresist layer and merely twice wet etchings thereafter are needed to realize the manufacture of the double layer gate electrode. The substrate does not need to be transferred in different chambers. Both the manufacture cost and the manufacture difficulty are low. A preferable embodiment according to the manufacture method of the double layer gate electrode of the present invention is illustrated with FIGS. 5 to 10.

As shown in FIG. 5, first, a first metal layer 120, a second metal layer 130 and a photoresist layer 140 are deposited on the substrate 110 sequentially; then, the photoresist layer 140 is patterned with a half tone mask 150. The middle of the half tone mask 150 is an opaque layer and two sides of the half tone mask 150 are semiopaque layers (the transmittance is about 50%). A width of the half tone mask 150 is the second width H2 and a width of the opaque layer of the half tone mask 150 is the first width H1. After the photoresist layer 140 is patterned with the aforesaid half tone mask 150, the shape of the photoresist layer 140 is shown in FIG. 6. The middle of the photoresist layer 140 is thicker and the two sides of the photoresist layer 140 are thinner. A width of the thicker part of the photoresist layer 140 is a first width H1 and a width of the whole photoresist layer 140 is a second width H2.

A wet etching is conducted to the structure shown in FIG. 6. The weight distribution of the etching liquid utilized in the wet etching is: H3PO4 50-60%: HNO3 10-20%: CH3COOH 2-10%: H2O 20-30%. In this embodiment, the weight distribution is preferable to be H3PO4 55%: HNO3 15%: CH3COOH 5%: H2O 25%. During the wet etching, the chemical reaction happened to the first metal layer 120 (such as the aluminum metal layer) is introduced below:
2Al+2H3P04 →4Al3++2P043−+3H2↑
3H2+2HN03→4H20+2N0↑

The chemical reaction happened to the first metal layer 120 (such as the aluminum metal layer) is introduced below:
Mo+2HN03→Mo03+H20+2N02↑
Mo03+H20→H Mo04 (intermediate)
12H2Mo04+H3P04→H3[P(Mo3O1O)4]+12H20

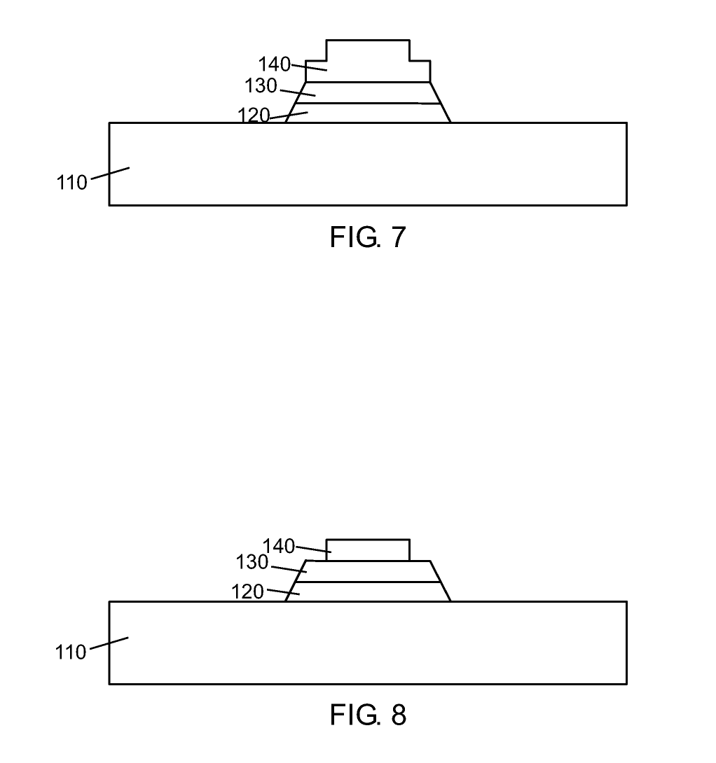

After the wet etching is conducted to the structure shown in FIG. 6, the first metal layer 120 and the second metal layer 130 are shaped in unison as a single layer structure as shown in FIG. 7.

Then, the thinner photoresist layer 140 of the structure shown in FIG. 7 at the two sides are removed by the photoresist ashing. Herein, ozonolysis photoresist ashing can be utilized. Within 80 degree Celsius and 120 degree Celsius, the ultraviolet light of the low pressure mercury lamp can be employed to cut chemical bonds of the photoresist in the photoresist layer 140 for ozonolysis. The ozonolysis oxygen radical reacts with the photoresist which chemical bonds are cut off to generate gaseous product. Accordingly, the photoresist layer 140 is removed as shown in FIG. 8.

Then, the wet etching is conducted again to the structure shown in FIG. 8. The weight distribution of the etching liquid utilized in the wet etching is: H3PO4 50-60%: HNO3 10-20%: CH3COOH 2-10%: H2O 20-30%. In this embodiment, the weight distribution is preferable to be H3PO4 55%: HNO3 15%: CH3COOH 5%: H2O 25%. During the wet etching, the chemical reaction happened to the first metal layer 120 (such as the aluminum metal layer) is introduced below:
Mo+2HN03→Mo03+H20+2N02↑
Mo03+H20→H2Mo04 (intermediate)
12H2Mo04+H3P04→H3[P Mo3O1O)4]+12H20

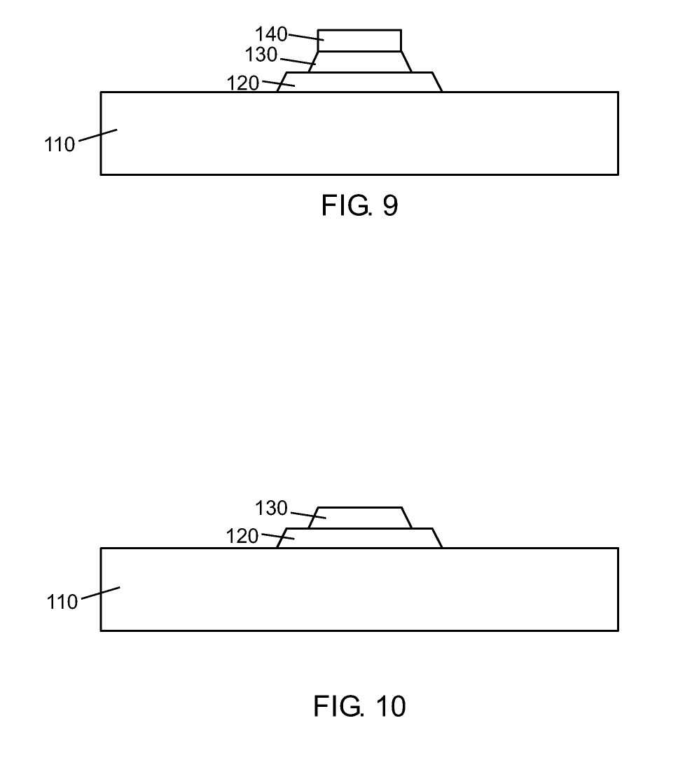

Because the second metal layer 130 is attached on the first metal layer 120, the corresponding second metal layer 130 is preferably etched and basically reaction does not happen to the first metal layer 120. After the wet etching is conducted to the structure shown in FIG. 8, the width of the second metal layer 130 is diminished to the first width H1 as shown in FIG. 9.

Last, the photoresist stripping is conducted to the photoresist layer 140. The structure after the photoresist stripping is shown in FIG. 10. The width of the first metal layer 120 is the second width H2 and the width of the second metal layer 130 is the first width H1. As can be seen from Figure, the double layer structure of the gate electrode shown in FIG. 10 is basically the same as that of the gate electrode shown in FIG. 4.

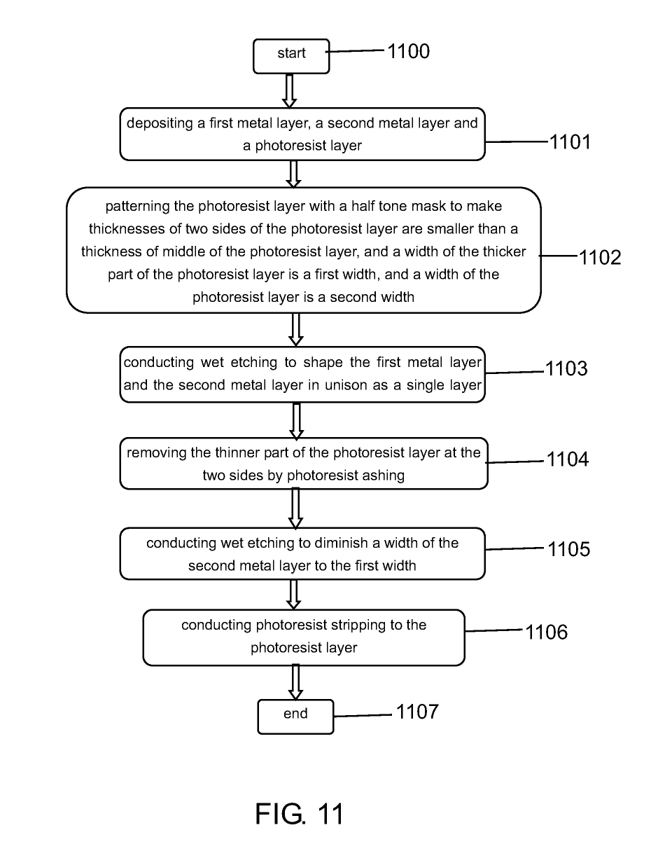

In FIG. 11 shows a flowchart of a preferable embodiment according to a manufacture method of a double layer gate electrode of the present invention, the manufacture method of the double layer gate electrode starts from Step 1100 and then:

Step 1101, depositing a first metal layer, a second metal layer and a photoresist layer;

Step 1102, patterning the photoresist layer with a half tone mask to make thicknesses of two sides of the photoresist layer are smaller than a thickness of middle of the photoresist layer, and a width of the thicker part of the photoresist layer is a first width, and a width of the photoresist layer is a second width;

Step 1103, conducting wet etching to shape the first metal layer and the second metal layer in unison as a single layer structure;

Step 1104, removing the thinner part of the photoresist layer at the two sides by photoresist ashing;

Step 1105, conducting wet etching to diminish a width of the second metal layer to the first width;

Step 1106, conducting photoresist stripping to the photoresist layer;

Last, the manufacture method of the double layer gate electrode ends at Step 1107.

As can be seen from the preferable embodiment shown in FIGS. 5 to 10 and the flowchart of the manufacture method shown in FIG. 11, the manufacture method of the double layer gate electrode according to the present invention can change one wet etching and one dry etching according to prior art into twice wet etchings. The substrate does not need to be transferred in different etching chambers for etching different metal layers of the gate electrode. Meanwhile, the manufacture cost of the dry etching is much higher, the manufacture methods of the double layer gate electrode according to the present invention is capable of lowering the manufacture difficulty and saving the manufacture cost.

The present invention also relates with a manufacture method of a thin film transistor comprises a manufacture of a double layer gate electrode, comprising steps of: S10, depositing a first metal layer, a second metal layer and a photoresist layer; S20, patterning the photoresist layer with a half tone mask to make thicknesses of two sides of the photoresist layer are smaller than a thickness of middle of the photoresist layer, and a width of the thicker part of the photoresist layer is a first width, and a width of the photoresist layer is a second width; S30, conducting wet etching to shape the first metal layer and the second metal layer as a single layer structure; S40, removing the thinner part of the photoresist layer at the two sides by photoresist ashing; S50, conducting wet etching to diminish a width of the second metal layer to the first width; S60, conducting photoresist stripping to the photoresist layer.

After the step S60, the width of the second metal layer is the first width and a width of the first metal layer is the second width; the middle of the half tone mask is an opaque layer and two sides of the half tone mask are semiopaque layers, and a width of the half tone mask is the second width and a width of the opaque layer is the first width.

The specific embodiment and the benefits of the manufacture method of the thin film transistor according to present invention are the same or similar to those of the manufacture method of the gate electrode. Please refer to the specific embodiment of the manufacture method of the gate electrode for reference.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A manufacture method of a double layer gate electrode, characterized in comprising steps of:
S10, depositing a first metal layer, a second metal layer and a photoresist layer;
S20, patterning the photoresist layer with a half tone mask to make thicknesses of two sides of the photoresist layer are smaller than a thickness of middle of the photoresist layer, and a width of the thicker part of the photoresist layer is a first width, and a width of the photoresist layer is a second width;
S30, conducting wet etching to shape the first metal layer and the second metal layer in unison as a single layer structure;
S40, removing the thinner part of the photoresist layer at the two sides by photoresist ashing;
S50, conducting wet etching to diminish a width of the second metal layer to the first width;
S60, conducting photoresist stripping to the photoresist layer;
the width of the second metal layer is the first width and a width of the first metal layer is the second width after the step S60;
the middle of the half tone mask is an opaque layer and two sides of the half tone mask are semiopaque layers, and a width of the half tone mask is the second width and a width of the opaque layer is the first width;
a weight distribution of an etching liquid of the wet etching is: H3PO4 50-60%: HNO3 10-20%: CH3COOH 2-10%: H2O 20-30%;
the photoresist ashing is to employ ultraviolet light to cut chemical bonds of the photoresist in the photoresist layer and to utilize ozonolysis oxygen radical to react with and remove the photoresist layer;
a temperature of the photoresist ashing is 80 degree Celsius to 120 degree Celsius;
the first metal layer is an aluminum metal layer;
the second metal layer is a molybdenum metal layer.

2. A manufacture method of a double layer gate electrode, characterized in comprising steps of:
S10, depositing a first metal layer, a second metal layer and a photoresist layer;
S20, patterning the photoresist layer with a half tone mask to make thicknesses of two sides of the photoresist layer are smaller than a thickness of middle of the photoresist layer, and a width of the thicker part of the photoresist layer is a first width, and a width of the photoresist layer is a second width;
S30, conducting wet etching to shape the first metal layer and the second metal layer in unison as a single layer structure;
S40, removing the thinner part of the photoresist layer at the two sides by photoresist ashing;
S50, conducting wet etching to diminish a width of the second metal layer to the first width;
S60, conducting photoresist stripping to the photoresist layer.

3. The manufacture method of the double layer gate electrode according to claim 2, characterized in that the width of the second metal layer is the first width and a width of the first metal layer is the second width after the step S60.

4. The manufacture method of the double layer gate electrode according to claim 2, characterized in that the middle of the half tone mask is an opaque layer and two sides of the half tone mask are semiopaque layers, and a width of the half tone mask is the second width and a width of the opaque layer is the first width.

5. The manufacture method of the double layer gate electrode according to claim 2, characterized in that a weight distribution of an etching liquid of the wet etching is: H3PO4 50-60%: HNO3 10-20%: CH3COOH 2-10%: H2O 20-30%.

6. The manufacture method of the double layer gate electrode according to claim 2, characterized in that the photoresist ashing is to employ ultraviolet light to cut chemical bonds of the photoresist in the photoresist layer and to utilize ozonolysis oxygen radical to react with and remove the photoresist layer.

7. The manufacture method of the double layer gate electrode according to claim 6, characterized in that a temperature of the photoresist ashing is 80 degree Celsius to 120 degree Celsius.

8. The manufacture method of the double layer gate electrode according to claim 2, characterized in that the first metal layer is an aluminum metal layer.

9. The manufacture method of the double layer gate electrode according to claim 2, characterized in that the second metal layer is a molybdenum metal layer.

10. A manufacture method of a thin film transistor, characterized in that the manufacture method comprises a manufacture of a double layer gate electrode, comprising steps of:
S10, depositing a first metal layer, a second metal layer and a photoresist layer;
S20, patterning the photoresist layer with a half tone mask to make thicknesses of two sides of the photoresist layer are smaller than a thickness of middle of the photoresist layer, and a width of the thicker part of the photoresist layer is a first width, and a width of the photoresist layer is a second width;
S30, conducting wet etching to shape the first metal layer and the second metal layer in unison as a single layer structure;
S40, removing the thinner part of the photoresist layer at the two sides by photoresist ashing;
S50, conducting wet etching to diminish a width of the second metal layer to the first width;
S60, conducting photoresist stripping to the photoresist layer.

11. The manufacture method of the thin film transistor according to claim 10, characterized in that the width of the second metal layer is the first width and a width of the first metal layer is the second width after the step S60.

12. The manufacture method of the thin film transistor according to claim 10, characterized in that the middle of the half tone mask is an opaque layer and two sides of the half tone mask are semiopaque layers, and a width of the half tone mask is the second width and a width of the opaque layer is the first width.

13. The manufacture method of the thin film transistor according to claim 10, characterized in that a weight distribution of an etching liquid of the wet etching is: H3PO4 50-60%: HNO3 10-20%: CH3COOH 2-10%: H2O 20-30%.

14. The manufacture method of the thin film transistor according to claim 10, characterized in that the photoresist ashing is to employ ultraviolet light to cut chemical bonds of the photoresist in the photoresist layer and to utilize ozonolysis oxygen radical to react with and remove the photoresist layer; a temperature of the photoresist ashing is 80 degree Celsius to 120 degree Celsius.

15. The manufacture method of the thin film transistor according to claim 10, characterized in that the first metal layer is an aluminum metal layer and the second metal layer is a molybdenum metal layer.
